(19) United States
(12) Patent Application Publication
(10) Pub. No.: US 2003/0111999 A1
(43) Pub. Date: Jun. 19, 2003

(54) Residential electricity meter

(76) Inventors: Ertugrul Berkcan, Clifton Park, NY (US); Naresh K. Rao, Clifton Park, NY (US)

Correspondence Address: John S. Beulick, Armstrong Teasdale LLP, Suite 2600, One Metropolitan Sq., St. Louis, MO, 63102, US

(21) Appl. No.: 10/026,151

(22) Filed: Dec. 19, 2001

(51) Int. Cl. G01R 31/02

(52) U.S. Cl. 324/117 H

(57) ABSTRACT

A current sensor for an apparatus includes a conductor having a slit and at least one Hall effect device inserted at least partially within the slit. The conductor is configured to generate a magnetic field having a pre-determined shape, and the Hall effect device is configured to detect the pre-determined shape and generate an output.

### BACKGROUND OF THE INVENTION

This invention relates generally to energy metering, and more particularly, to single-phase electricity metering.

Metering energy consumption by loads coupled to a single phase of a power line, such as residences, typically is performed by a mechanical meter including a disk which rotates at a rate related to energy consumption. The disk drives gears coupled to a mechanical register that includes rotatable indicators that display energy consumption, e.g., kilowatt-hour. Although mechanical meters are extremely reliable and cost effective for residential metering, such meters display limited data and are not readily configurable for specific applications, e.g., functionality is not easily added to such meters when installed in the field.

Meters that perform both the metering and register functions using electronic components, i.e., no rotating disk, sometimes are referred to as electronic, or solid state, meters. Although such meters generate and communicate multiple metering quantities in addition to kilowatt hour, such meters are more expensive than mechanical meters in both component cost as well as fabrication cost. As a result, electronic meters typically are utilized in commercial and industrial metering, i.e., higher revenue metering sites, rather than in residential metering.

### BRIEF SUMMARY OF THE INVENTION

In one embodiment, a current sensor for an apparatus is provided. The current sensor includes a conductor having a slit and at least one Hall effect device inserted at least partially within the slit. The conductor is configured to generate a magnetic field having a pre-determined shape, and the Hall effect device is configured to detect the pre-determined shape and generate an output.

In another embodiment, a residential electricity meter including a voltage sensor and a current sensor is provided. The current sensor includes a conductor having a slit and at least one Hall effect device inserted at least partially within the slit. The conductor is configured to generate a magnetic field having a pre-determined shape, and the Hall effect device is configured to detect the pre-determined shape and generate an output.

In a further embodiment, a method for sensing voltage and current in a residence is provided. The method includes providing an electricity meter. The meter includes a voltage sensor and a current sensor. The current sensor includes a conductor having a slit and at least one Hall effect device inserted at least partially within the slit. The conductor is configured to generate a magnetic field having a pre-determined shape, and the Hall effect device is configured to detect the pre-determined shape and generate an output.

### BRIEF DESCRIPTION OF THE DRAWINGS

FIG. 1 is a side view of an exemplary embodiment of a current sensor.

FIG. 2 is a perspective view of a conductor for receiving a current sensor illustrated.

FIG. 3 is a side view of another embodiment of a current sensor.

FIG. 4 is block diagram of a Hall effect based electronic electricity meter.

### DETAILED DESCRIPTION OF THE INVENTION

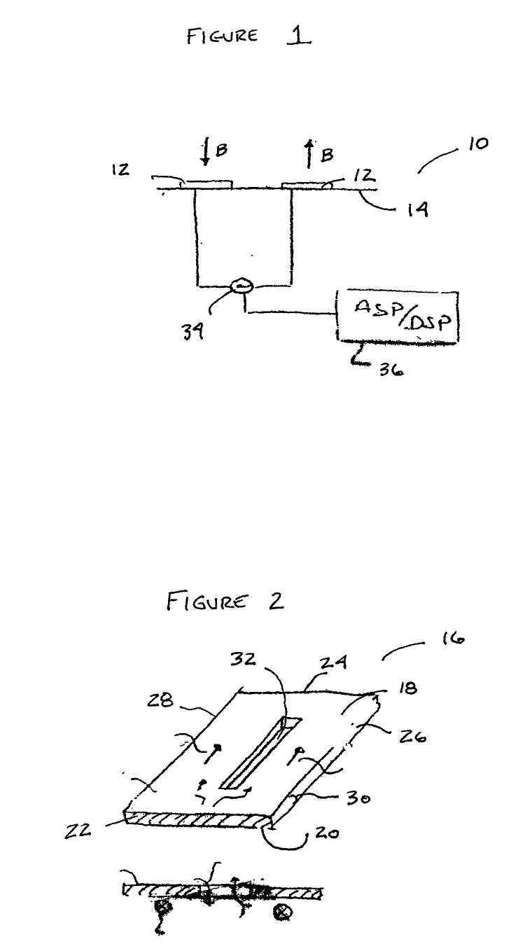

FIG. 1 is a side view of an exemplary embodiment of a current sensor 10 including a plurality of Hall effect devices 12 disposed on a substrate 14, such as a substrate of an integrated circuit or a substrate of a printed circuit board. In another embodiment, current sensor 12 includes any sensor capable of sensing a magnetic field. In one embodiment, current sensor 10 includes at least two Hall effect devices 12. In another embodiment, current sensor 10 includes a single Hall effect device 12. In an alternative embodiment, current sensor 10 includes more than two Hall effect devices 12.

FIG. 2 is a perspective view of a conductor 16 for receiving Hall effect devices 12. Conductor 16 is unitary and fabricated using a conductive material. In an alternative embodiment, conductor 14 is non-unitary. Conductor 16 includes a first side 18, a second side 20, a first edge 22, a second edge 24, a third edge 26, a fourth edge 28, and a thickness 30. Conductor 16 also includes a slot 32 extending from first side 18 to second side 20. Slot 32 is located at the approximate geometric center of conductor 16. Slot 32 is designed such that a current introduced at first edge 22 is divided into two approximately equal current components. Current sensor 10 is inserted at least partially into slot 32 and facilitates detecting a magnetic field created by current carrying conductor 16. The current components then generate two magnetic field components that are shaped such that they are substantially in the opposite direction and substantially equal in magnitude.

In use, a chip or a circuit board containing a pair of Hall effect devices 12 is disposed in slot 32 where a magnetic field B has the desired spatial behavior. A current is introduced into conductor 16 thereby generating a magnetic field having a pre-determined shape around conductor 16. In one embodiment, the magnetic field is shaped by slot 32 such that a pre-determined spatial dependence is introduced into the magnetic field. In another embodiment, the magnetic field can be any shape around conductor 16 based on the design of conductor 16. The pre-determined shape of the magnetic field is then detected by Hall effect devices 12. In one embodiment, Hall effect devices 12 are inserted into slot 32 such that they are particularly sensitive to the shaping of the magnetic field. Therefore, a resulting Hall effect device signal output is insensitive to magnetic fields having other than the pre-determined spatial dependence since external magnetic fields are generally smoothly varying over the distances and scales where the spatial dependence exists. Additionally, a signal processing, due to its differential nature, is used to remove geometric and material non-linearity in the output of the Hall effect devices 12. In one embodiment, Hall effect devices 12 output includes a non-linear component which is generally of the form (μ_{H}B)², and substantially even in the magnetic flux density, where μ_{H} is a Hall mobility, and B is a magnetic field. Therefore, the evenness in the non-linear term is exploited to remove it from the output of the sensor by using the same signal processing and geometrical factors.

Referring again to FIG. 1, the components of the magnetic field B perpendicular to substrate 14 on which two Hall effect devices 12 have been disposed are shown. In one embodiment, the magnetic field includes at least a first magnetic field component having a first direction and a second magnetic field component having a second direction different from the first direction. Hall effect devices 12 are placed a pre-determined distance from each other such a Hall effect device 12 can detect least a first magnetic field component having a first direction and another Hall effect device can detect a second magnetic field component having a second direction different from the first direction. The magnetic field B components are created in such a way that they substantially change direction over a relatively short distance. In one embodiment, Hall effect devices 12 outputs are processed using a differential signal processing circuit 34, such as, but not limited to, a difference calculator. Differential signal processing circuit 34 output is then processed by an analog and digital signal processing circuit 36 for further processing and calculations.

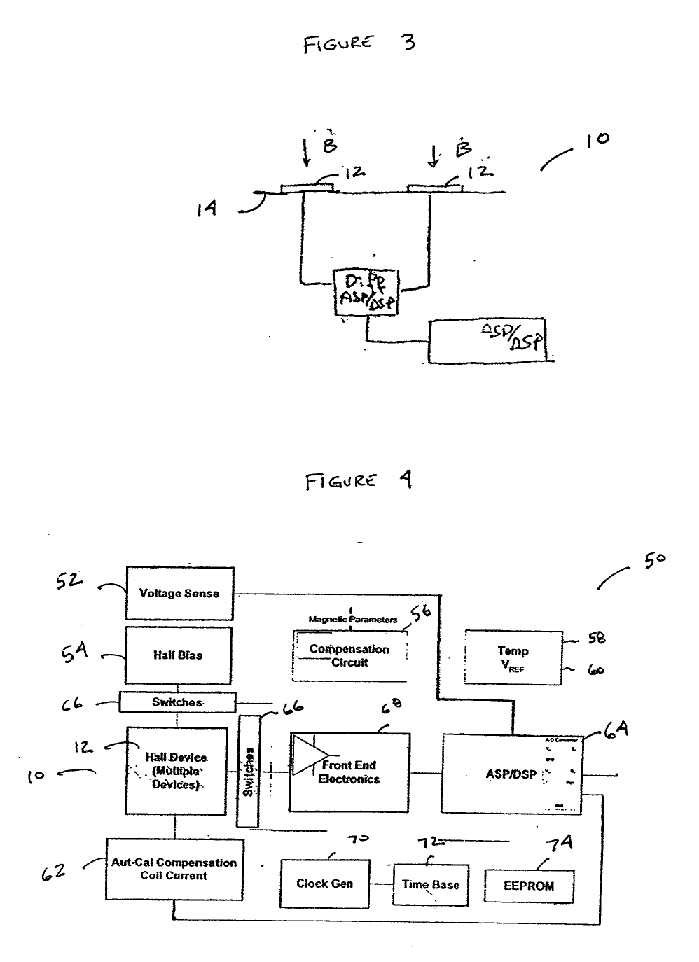

FIG. 3 is a side view of another embodiment of a current sensor 10 relative to a plurality of magnetic fields having the same direction. In one embodiment, the spatial dependence and the shaping of the magnetic field B and a resulting difference in the two magnetic field B components are processed by a signal processing circuitry 38 that is sensitive to this difference. For example, sensor 10 may include a magnetic field B including at least a first magnetic field component having a first direction and a second magnetic field component having a second direction the same as the first direction but varying by a known spatial variation.

FIG. 4 is block diagram of a Hall effect based electronic electricity meter 50, such as a residential electricity meter 50. In one embodiment, electricity meter 50 includes a voltage sensor 52 which includes a plurality of resistors (not shown). Electricity meter 50 also includes a current sensor 10, including at least one Hall effect device 12 designed to be both sensitive to the magnetic field B created by a current carrying conductor 16 (shown in FIG. 2), and their particular spatial dependence, as described herein. Hall effect devices 12 are biased by Hall bias electronics 54. In one embodiment, a compensation circuit 56, temperature sensor 58, and voltage reference signal 60 are used to generate a bias correction. More specifically, the output of Hall effect device 12 is temperature dependant and compensation circuit 56 at least partially removes the temperature dependency from the output. Additionally, the Hall effect device 12 bias can be selected to be dependent upon a voltage reference signal 60 to obtain an analog multiplication in Hall effect device 12. In one embodiment, voltage reference signal 60 is generated using a voltage signal generator (not shown) such as, but not limited to, a bandgap cell designed to generate an accurate and constant voltage reference signal. Alternatively, the Hall effect device 12 bias can be selected to be dependent on a temperature sensor 58 to provide a temperature correction for the output of Hall effect device 12. In one embodiment, temperature sensor 58 generates a temperature sensor output based on the temperature of Hall effect device 12 substrate temperature.

Electric meter 50 also includes an auto-compensation circuit 62 and a compensation coil (not shown) which are used to perform an auto-calibration of current sensor 10. A signal processing device 64 includes an analog signal processor and a digital signal processor (ASP/DSP). Signal processing block 64 is used to control the compensation and calibration of Hall effect devices 12.

Electric meter 50 also includes an a plurality of switches 66 which are used to select a particular Hall effect device 12 from the multiple set of Hall effect devices 12, for signal processing and to obtain a geometrical rotation of the Hall effect devices 12 to remove an offset voltage. A front-end electronics device 68 is used to condition outputs of Hall effect devices 12 and provide the conditioned outputs as signal outputs to signal processing device 64. Additionally, front end device 68 includes voltage sensing circuitry which is used by signal processing device 64 to digitize the signals, and a clock generator 70 and a time base 72 to calculate a power and an electrical energy use of any apparatus connected to electricity meter 10. Electric meter 50 also includes a memory device 74, such as, but not limited to, an EEPROM to store a plurality of factory floor calibration values and a plurality of auto-calibration values obtained during electric meter 50 operation.

While the invention has been described in terms of various specific embodiments, those skilled in the art will recognize that the invention can be practiced with modification within the spirit and scope of the claims.

What is claimed is:

1. A current sensor for an apparatus, said current sensor comprising a conductor comprising a slit and at least one Hall effect device inserted at least partially within said slit, said conductor is configured to generate a magnetic field having a pre-determined shape, said Hall effect device configured to detect said pre-determined shape and generate an output.

2. An apparatus in accordance with claim 1 wherein said apparatus comprises a residential electricity meter.

3. A current sensor in accordance with claim 1 wherein said magnetic field has a pre-determined spatial dependence.

4. A sensor in accordance with claim 1 wherein said Hall effect device output is substantially insensitive to magnetic fields having other than the pre-determined shape.

5. A sensor in accordance with claim 1 wherein said current sensor further comprises a plurality of Hall effect devices.

6. A sensor in accordance with claim 1 wherein said Hall effect device output comprises a non-linear component.

7. A sensor in accordance with claim 5 wherein said plurality of Hall effect devices are separated by a pre-determined distance.

8. A sensor in accordance with claim 1 wherein said magnetic field comprises at least a first magnetic field component having a first direction and a second magnetic field component having a second direction different from said first direction.

9. A sensor in accordance with claim 1 wherein said magnetic field comprises at least two magnetic field components having the same direction.

10. A current sensor for an apparatus comprising a slit and at least one Hall effect device inserted at least partially within said slit, said conductor is configured to generate a magnetic field comprising at least a first magnetic field component having a first direction and a second magnetic field component having a second direction different from said first direction, and a pre-determined shape, said Hall effect device configured to detect said pre-determined shape and generate an output.

11. A residential electricity meter comprising a voltage sensor and a current sensor, said current sensor comprising a conductor comprising a slit and at least one Hall effect device inserted at least partially within said slit, said conductor is configured to generate a magnetic field having a pre-determined shape, said Hall effect device configured to detect said pre-determined shape and generate an output.

12. An electricity meter in accordance with claim 11 wherein said electricity meter comprises a residential electricity meter.

13. An electricity meter in accordance with claim 11 wherein said magnetic field has a pre-determined spatial dependence.

14. An electricity meter in accordance with claim 11 wherein said Hall effect device output is insensitive to magnetic fields having other than the pre-determined shape.

15. An electricity meter in accordance with claim 11 wherein said current sensor further comprises a plurality of Hall effect devices.

16. An electricity meter in accordance with claim 11 wherein said Hall effect device output comprises a non-linear component.

17. An electricity meter in accordance with claim 15 wherein said plurality of Hall effect devices are each separated by a pre-determined distance.

18. An electricity meter in accordance with claim 11 wherein said magnetic field comprises at least a first magnetic field component having a first direction and a second magnetic field component having a second direction different from said first direction.

19. An electricity meter in accordance with claim 11 wherein said magnetic field comprises at least two magnetic field components having the same direction.

20. A residential electricity meter comprising a voltage sensor and a current sensor, said current sensor comprising a conductor comprising a slit and at least one Hall effect device inserted at least partially within said slit, said conductor is configured to generate a magnetic field comprising at least a first magnetic field component having a first direction and a second magnetic field component having a second direction different from said first direction, and a pre-determined shape, said Hall effect device configured to detect said pre-determined shape and generate an output

21. A method for sensing voltage and current in a residence, said method comprising:
providing an electricity meter comprising:
a voltage sensor; and
a current sensor, wherein the current sensor comprises a conductor comprising a slit and at least one Hall effect device inserted at least partially within the slit, wherein the conductor is configured to generate a magnetic field having a pre-determined shape, and the Hall effect device is configured to detect the pre-determined shape and generate an output.

22. A method in accordance with claim 21 wherein providing an electricity meter comprises providing a residential electricity meter.

23. A method in accordance with claim 21 further comprising providing a conductor configured to generate a magnetic field having a pre-determined spatial dependence.

24. A method in accordance with claim 21 further comprising providing a Hall effect device output comprising a non-linear component.

25. A method in accordance with claim 21 further comprising providing a plurality of Hall effect devices.

26. A method in accordance with claim 25 wherein said plurality of Hall effect devices are each separated by a pre-determined distance.

27. A method in accordance with claim 21 further comprising providing a conductor configured to generate a magnetic field comprising at least a first magnetic field component having a first direction and a second magnetic field component having a second direction different from the first direction.

28. A method in accordance with claim 21 further comprising providing a conductor configured to generate a magnetic field comprising at least a first magnetic field component having a first direction and a second magnetic field component having a second direction the same as the first direction.

29. A method for sensing voltage and current in a residence, said method comprising:
providing a residential electricity meter comprising:
a voltage sensor; and
a current sensor, said current sensor comprising a conductor comprising a slit and at least one Hall effect device inserted at least partially within said slit, said conductor is configured to generate a magnetic field comprising at least a first magnetic field component having a first direction and a second magnetic field component having a second direction different from said first direction, and a pre-determined shape, said Hall effect device configured to detect said pre-determined shape and generate an output
